(19) United States
(12) Patent Application Publication
(10) Pub. No.: US 2012/0239337 A1
(43) Pub. Date: Sep. 20, 2012

(54) SEMICONDUCTOR INTEGRATED CIRCUIT, TEST METHOD AND INFORMATION PROCESSING APPARATUS

(75) Inventor: Tatsuru Matsuo, Kawasaki (JP)

(73) Assignee: FUJITSU LIMITED, Kawasaki-shi (JP)

(21) Appl. No.: 13/343,015

(22) Filed: Jan. 4, 2012

(30) Foreign Application Priority Data
Mar. 18, 2011 (JP) 2011-061323

(51) Int. Cl. G01R 31/3177

(52) U.S. Cl. 702/119

(57) ABSTRACT

A semiconductor integrated circuit includes a plurality of shift registers to which test patterns are supplied, a pseudorandom number generator configured to generate, based on the test patterns supplied to the shift registers, pseudorandom numbers utilized as masking information corresponding to output responses of the shift registers, a masking information inverter configured to invert, on receiving a first control signal, the masking information corresponding to the output responses of the shift registers indicated by the first control signal, and an initial value storage configured to store initial values of the pseudorandom numbers. In the semiconductor integrated circuit, the pseudorandom numbers generated by the pseudorandom number generator are, on receiving a second control signal, initialized with the initial values of the pseudorandom numbers stored in the initial value storage.

### CROSS-REFERENCE TO RELATED APPLICATION

This patent application is based upon and claims the benefit of priority of Japanese Patent Application No. 2011-061323 filed on Mar. 18, 2011, the entire contents of which are incorporated herein by reference.

### FIELD

The embodiments discussed herein are related to a semiconductor integrated circuit, a test method, an information processing apparatus, and a computer-readable medium.

### BACKGROUND

A built-in self-test (BIST) is generally utilized as a test method for detecting defective products of semiconductor integrated circuits (hereinafter simply called an “LSI” for “Large Scale Integration”).

FIG. 1 is a diagram illustrating such a BIST to be performed on the LSI. As illustrated in FIG. 1, an LSI 1030 is a target LSI on which the BIST (hereinafter also called the “test”) is to be performed. The LSI 1030 includes two or more scan paths SP, a pseudorandom number generator circuit 1031 and an signature analysis circuit 1032. The pseudorandom number generator circuit 1031 and the signature analysis circuit 1032 are additional components for conducting the test. Each of the scan paths SP includes two or more flip-flops (FFs). The test is performed on the LSI 1030 according to the following procedure by an LSI tester 1020, which is controlled based on pre-generated test data.

(1) Test patterns generated by the pseudorandom number generator circuit 1031 are set into the respective flip-flops via the respective scan paths SP.
(2) Subsequently, output responses acquired from the LSI 1030 corresponding to the test patterns supplied to the LSI 1030 are stored in the respective flip-flops.
(3) The output responses stored in the flip-flops are then supplied to the signature analysis circuit 1032 via the respective scan paths SP. The signature analysis circuit 1032 compresses the supplied output responses.
(4) When the above processes (1) to (3) are conducted corresponding to all the intended test patterns, the compressed output responses are output into the LSI tester 1020.
(5) The LSI tester 1020 compares the compressed output responses output from the signature analysis circuit 1032 with respective expected values generated in advance by circuit simulation to subsequently determine a test result.

In the BIST, the test patterns to be supplied to the LSI 1030 are generated by the pseudorandom number generator circuit 1031. Accordingly, the LSI tester 1020 may not have to store the test patterns. The LSI tester 1020 may store only an initial value of the pseudorandom number generator circuit 1031. Thus, it may be possible to reduce the amount of test data loaded in limited memory resources of the LSI tester 1020.

However, there is restriction in the BIST. That is; it is not desirable that unknown values be input to the signature analysis circuit 1032 while the BIST is performed. Specifically, it is not desirable that the output responses contain the unknown values in the BIST. If the output response containing the unknown value is input to the signature analysis circuit 1032, the compressed content of the output response may be corrupted. As a result, it may not be possible to carry out the test (BIST) on the LSI 1030. Note that the unknown value is defined as an uncertain output response a value of which may be 0 or 1 at the time of testing the LSI 1030. In general, sequential circuit elements including a RAM inside the LSI are in an unknown status when the power is supplied. Consequently, output responses from such sequential circuit elements may be unknown values.

Thus, a circuit for masking the unknown values may be additionally provided as a countermeasure to prevent the unknown values from being supplied to the signature analysis circuit 1032.

FIG. 2 is a diagram illustrating an example of the LSI including an unknown value masking circuit. In FIG. 2, elements identical to those illustrated in FIG. 1 are provided with the same reference numerals and descriptions of such elements are omitted.

In FIG. 2, an LSI 1030a includes an unknown value masking circuit 1033 arranged on an input side of the signature analysis circuit 1032.

The unknown value masking circuit 1033 is configured to mask an unknown value contained in the output response by specifying (correcting) the unknown value to a fixed value of 0 or 1. Since the unknown value is masked by the unknown value masking circuit 1033, the unknown value may not be supplied to the signature analysis circuit 1032.

Note that which one of the output responses is to be masked may be controlled by the LSI tester 1020 based on the test data. That is, information indicating which one of the output responses to be masked (hereinafter called “masking information”) is stored in the test data. Accordingly, an increase of the masking information may increase the amount of the test data. In this respect, it may be desirable to reduce the amount of the masking information. For example, in a technology disclosed in Japanese Laid-open Patent Publication No. 2007-322414, a pseudorandom number generator circuit generates masking information at the time of testing the LSI. With this configuration, it may not be necessary to store the masking information in the test data. Further, if the masking information generated by the pseudorandom number generator circuit exhibits no adverse effect, it may be possible to reduce the amount of the test data due to the unstored amount of the masking information.

However, when a pseudorandom number itself is utilized as the masking information, the output response indicating the unknown value may not necessarily be masked.

Or, a failure value may be masked. The failure value indicates an output response indicating a value that may differ when the LSI 1030 is a defective product and when the LSI 1030 is a non-defective product. Since the failure value is utilized for determining whether the LSI 1030 is a defective product or a non-defective product, it is undesirable to mask the failure value.

Thus, in the technology disclosed in Patent Document 1, a circuit configured to invert part of the masking information (hereinafter called a “masking information inverter circuit”) is utilized for correcting the masking information generated based on the pseudorandom number. The masking information inverter circuit is configured to invert a bit that unmasks an unknown value or a bit that masks the failure value in the masking information. As a result, the unmasking of the unknown value or the masking of the failure value may be prevented.
[Patent Document 1] Japanese Laid-open Patent Publication No. 2007-322414

### SUMMARY

According to an aspect of an embodiment, there is provided a semiconductor integrated circuit that includes a plurality of shift registers to which test patterns are supplied; a pseudorandom number generator configured to generate, based on the test patterns supplied to the shift registers, pseudorandom numbers utilized as masking information corresponding to output responses of the shift registers; a masking information inverter configured to invert, on receiving a first control signal, the masking information corresponding to the output responses of the shift registers indicated by the first control signal; and an initial value storage configured to store initial values of the pseudorandom numbers. In the semiconductor integrated circuit, the pseudorandom numbers generated by the pseudorandom number generator are, on receiving a second control signal, initialized with the initial values of the pseudorandom numbers stored in the initial value storage.

The object and advantages of the invention will be realized and attained by means of the elements and combinations particularly pointed out in the appended claims.

It is to be understood that both the foregoing general description and the following detailed description are exemplary and explanatory and are not restrictive of the invention, as claimed.

Additional objects and advantages of the embodiments will be set forth in part in the description which follows, and in part will be obvious from the description, or may be learned by practice of the invention.

### BRIEF DESCRIPTION OF THE DRAWINGS

FIG. 1 is a diagram illustrating a built-in self-test (BIST);

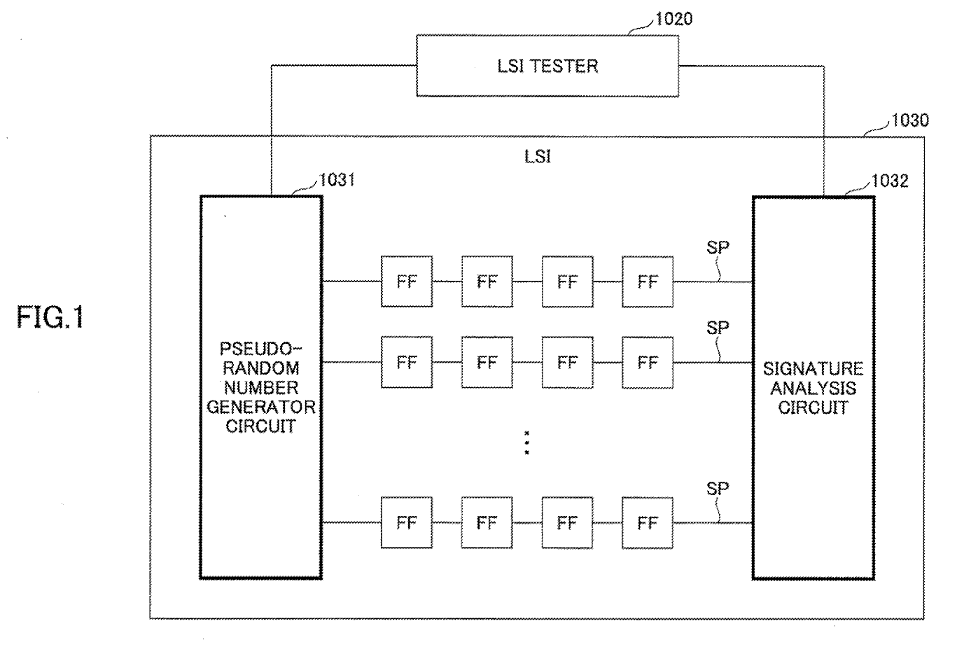

FIG. 2 is a diagram illustrating an example of an LSI including an unknown value masking circuit;

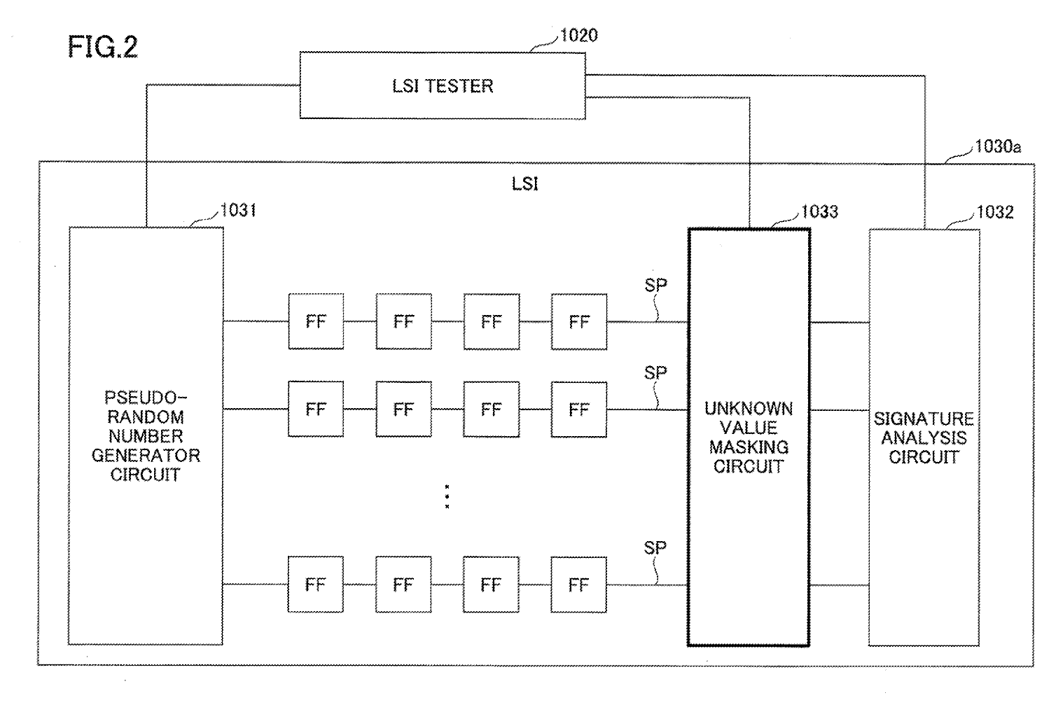

FIG. 3 is a schematic diagram illustrating an LSI test according to an embodiment;

FIG. 4 is a diagram illustrating a configuration example of an LSI according to an embodiment;

FIG. 5 is a diagram illustrating a configuration example of an unknown value masking part;

FIG. 6 is a diagram illustrating the configuration examples of an initial value storage and a masking information generator;

FIG. 7 is a diagram illustrating a hardware configuration example of test data generator device according to an embodiment;

FIG. 8 is a diagram illustrating a functional configuration example of the test data generator device according to the embodiment;

FIG. 9 is a flowchart illustrating an example of a test data generating procedure;

FIG. 10 is a diagram illustrating an example of data indicating control signals for inverting shifting information or masking information;

FIG. 11 is a diagram illustrating a specific example in which whether to invert the masking information is determined;

FIG. 12 is a diagram illustrating a specific example of control data for inverting the masking information;

FIG. 13 is a diagram illustrating a configuration example of an LSI tester according to an embodiment;

FIG. 14 is a diagram illustrating an example in which the masking information is inverted at the time of performing an actual test;

FIG. 15 is a flowchart illustrating an example of a masking information initial value generating procedure; and

FIG. 16 is a diagram illustrating an example of a process of searching initial values of the masking information of all the flip-flops in a specific flip-flop group.

### DESCRIPTION OF EMBODIMENTS

In the technology disclosed in Patent Document 1, an inverting instruction for inverting the masking information addressed to the masking information inverter circuit is stored in the test data. Accordingly, if the number of times that the masking information is inverted is increased, the amount of the test data may be increased accordingly.

In this respect, it is desirable to provide a semiconductor integrated circuit, a testing method for testing the semiconductor integrated circuit, an information processing apparatus and a non-transitory medium that may reduce the number of times that the masking information is inverted.

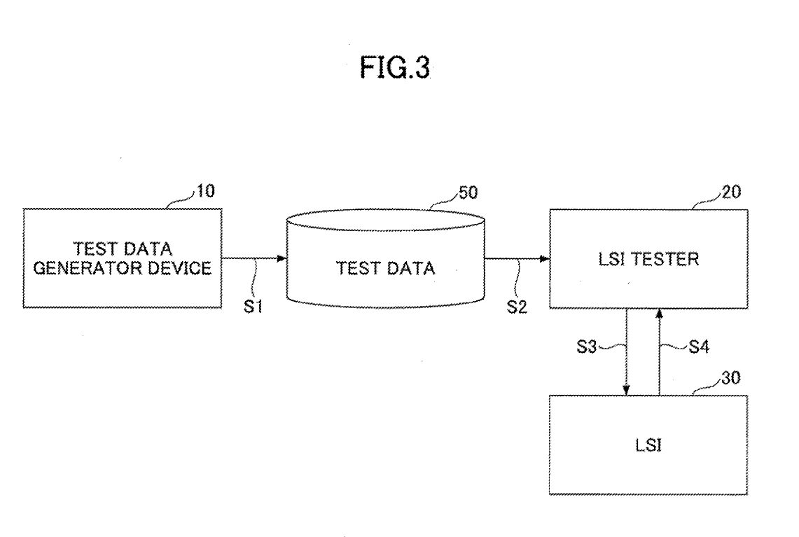

In the following, a description is given, with reference to the accompanying drawings, of embodiments. FIG. 3 is a schematic diagram illustrating an LSI test according to an embodiment.

Initially, a test data generator device 10 generates test data 50 (step S1). The test data 50 represents data including information representing control signals supplied to a semiconductor integrated circuit (LSI) 30 that is subject to the LSI test. The test data 50 further includes an expected value or the like corresponding to a value output from the LSI 30 when the test is conducted on the LSI 30.

The generated test data 50 are set into an LSI tester 20 (step S2). The LSI tester 20 supplies a control signal to the LSI 30 based on the test data 50 set into the LSI 30 (step S3). The LSI tester 20 compares the value output based on the supplied control signal from the LSI 30 with the expected value contained in the test data 50 to detect a defect of the LSI 30 (step S4). That is, if the value output by the LSI 30 does not match the expected value contained in the test data 50, the LSI tester 20 determines that the LSI 30 is a defective product.

Note that the LSI tester 20 may, in general, be a commercially available LSI tester. However, alternatively, an information processing apparatus, on which a computer program causing a computer to function as the LSI tester is installed, may be utilized as the LSI tester 20.

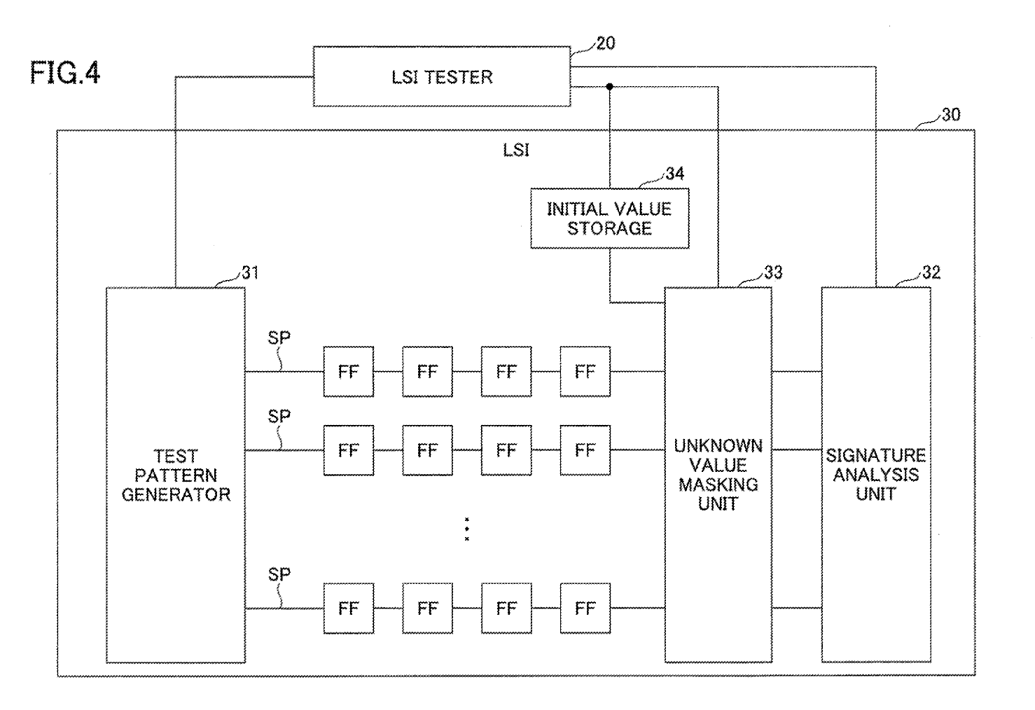

FIG. 4 is a diagram illustrating a configuration example of an LSI according to an embodiment. As illustrated in FIG. 4, an LSI 30 includes a test pattern generator 31, shift-register scan paths SP, an signature analysis unit 32, an unknown value masking part 33 and an initial value storage 34.

The test pattern generator 31 is configured to generate (or output) a pseudorandom number supplied to each of the scan paths SP as a test pattern at the time of testing the LSI 30. Note that the test pattern generator 31 may also be called a pseudorandom pattern generator (PRPG). When the test patterns are supplied to the flip-flops (FFs) contained in the respective scan paths (shift registers), a value corresponding to the supplied test pattern is recorded in each of the flip-flops (FFs).

The scan path SP is a circuit partially forming a target circuit to be tested (hereinafter called a “testing circuit”). After the test patterns are input to the FFs, clock signals are supplied to the LSI 30. Then, a not-illustrated logic circuit outputs (records) output responses (output values) corresponding to the test patterns into the respective FFs.

The unknown value masking part 33 is configured to mask the output responses of the scan paths SP specified as masking targets in the test data 50. Note that to “mask” or “masking” in this embodiment indicates correcting the output responses of “0” or “1” to a fixed value. That is, the unknown value masking part 33 eliminates the unknown values from the output responses. The information indicating the masking target (i.e., the masking information) may be generated based on the pseudorandom number. The unknown value masking part 33 may optionally invert parts of the bits composed of the masking information for correcting the masking information based on the pseudorandom number. The inversion of part of the bits forming the masking information (the masking information inversion) may be executed by the control signals input from the LSI tester 20 based on the test data 50. That is, the test data 50 includes an inverting instruction for inverting the masking information.

The signature analysis unit 32 compresses the output responses that are output from the scan paths SP and masked (excluding unknown values) by the unknown value masking part 33. The compressed output responses are output to the LSI tester 20 and then compared with the expected values corresponding to the test patterns. The expected values are generated in advance by the test data generator device 10 based on circuit simulation and stored in the test data 50. The test patterns identical to those generated by the test pattern generator 31 are utilized in the circuit simulation. That is, since the test patterns generated by the test pattern generator 31 are pseudorandom numbers, the test patterns may include reproducibility in the generated order of the pseudorandom numbers. Thus, it may be possible to reproduce the test patterns identical to those generated by the test pattern generator 31 in the circuit simulation. The output responses of the circuit simulation corresponding to the test patterns are stored in the test data 50 as the expected values.

The initial value storage 34 is configured to store values as initial values of the pseudorandom numbers generated by the unknown value masking part 33. Based on such initial values stored in the initial value storage 34, the number of times that the masking information is inverted may be reduced. The initial values are searched for (or computed) by the test data generator device 10 and the obtained initial values are stored in the test data 50. Note that reduction in the number of times that the masking information is inverted indicates eliminating instructions for inverting the masking information from the test data 50. That is, the test data 50 may be reduced based on the initial values stored in the initial value storage 34.

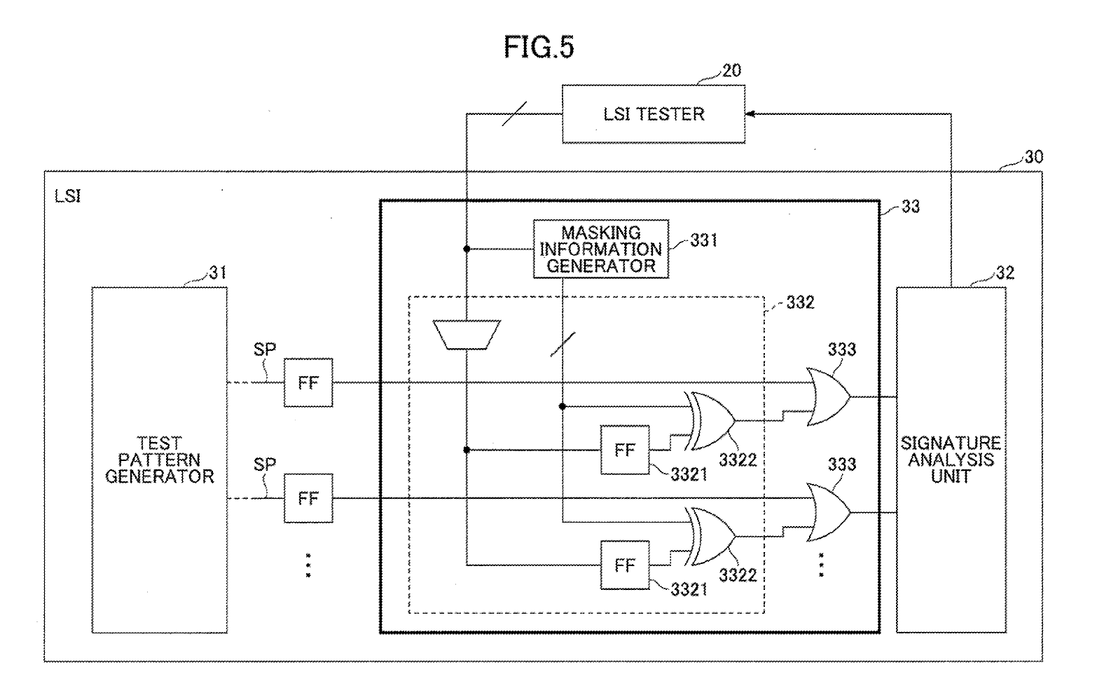

The unknown value masking part 33 is described further in detail. FIG. 5 is a diagram illustrating a configuration example of the unknown value masking part 33. As illustrated in FIG. 5, the unknown value masking part 33 includes the masking information generator 331, the masking information inverter 332, and OR circuits 333 corresponding to the scan paths SP.

The masking information generator 331 is a circuit configured to generate a pseudorandom number (i.e., pseudorandom number generator PRPG). That is, the pseudorandom number is the masking information. The masking information is information composed of N bits when the number of scan paths SP is N. That is, one of N bits corresponds to one of the scan paths SP. The masking information generator 331 utilizes values stored in the initial value storage 34 as initial values of the pseudorandom numbers (the masking information).

Each of the OR circuits 333 outputs a logical OR of the output response (output value) from the corresponding scan path SP and an output value of the masking information inverter 332. Thus, if the output value from the masking information inverter 332 is “1”, a value to be input to the signature analysis unit 32 is determined as “1”, regardless of the value of the output response from the corresponding scan path SP (i.e., the value is masked).

The masking information inverter 332 includes a flip-flop (FF) 3321 and an EXOR circuit 3322 for each of the scan paths SP. Each of the FFs 3321 stores a value of “0” or “1”. When the masking information generator 331 supplies a value “0” to the scan path associated with the FF 3321 that stores a value “0”, the corresponding EXOR circuit 3322 outputs a value “0”. Likewise, when the masking information generator 331 supplies a value “1” to the scan path associated with the FF 3321 that stores a value “0”, the corresponding EXOR circuit 3322 outputs a value “1”. That is, if the FF 3321 stores a value “0”, the masking value inverter 332 outputs the same value as the value that the masking information generator 331 supplies to the scan path.

On the other hand, when the masking information generator 331 supplies a value “0” to the scan path associated with the FF 3321 that stores a value “1”, the corresponding EXOR circuit 3322 outputs a value “1”. Likewise, when the masking information generator 331 supplies a value “1” to the scan path associated with the FF 3321 that stores a value “1”, the corresponding EXOR circuit 3322 outputs a value “0”. That is, if the FF 3321 stores a value “1”, the masking value inverter 332 outputs the inverted value of the value that the masking information generator 331 supplies to the scan path. Thus, the LSI tester 20 stores a value “1” in the FF 3321 associated with the scan path via which the masking information is desired to be inverted based on the test data 50.

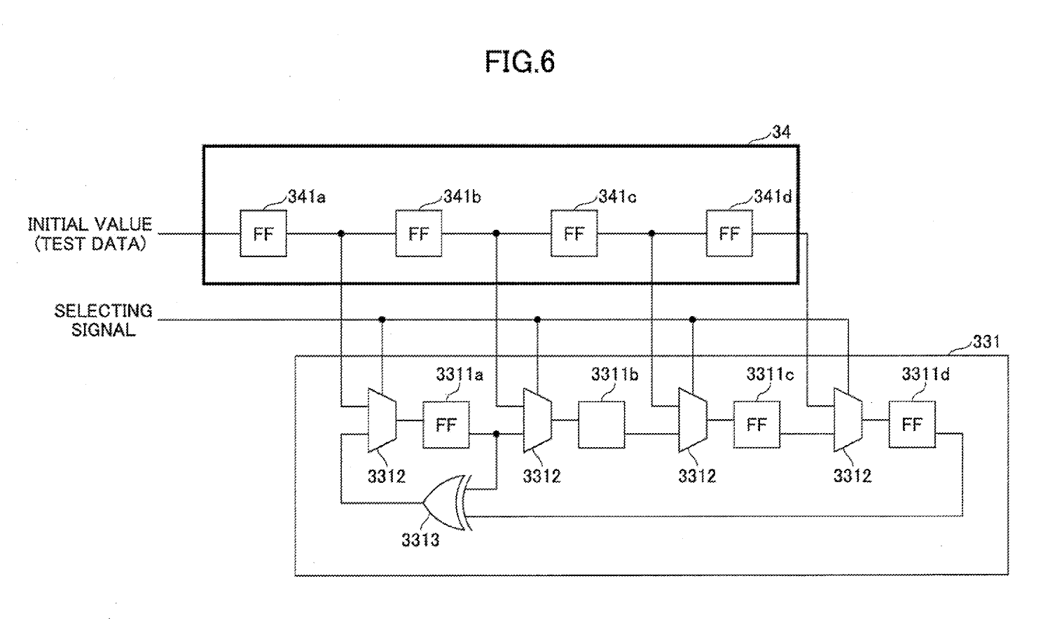

Next, configuration examples of the initial value storage 34 and the masking information generator 331 are described. FIG. 6 is a diagram illustrating the configuration examples of the initial value storage 34 and the masking information generator 331. FIG. 6 illustrates the configuration examples of the initial value storage 34 and the masking information generator 331 in a case where the number of scan paths SP of the LSI 30 is four.

As illustrated in FIG. 6, the masking information generator 331 includes four flip-flops (FFs) 3311a to 3311d (hereinafter also collectively called a “flip-flop 3311”) corresponding to the number of the scan paths SP (four flip-flops in this case). Accordingly, the masking information (pseudorandom number) generated by the masking information generator 331 illustrated in FIG. 6 is 4-bit information. The four flip-flops (FFs) 3311a to 3311d form a shift register. Specifically, the flip-flops (FFs) 3311a to 3311d are cascade connected such that the respective values stored in the flip-flops 3311a to 3311d are sequentially shifted. In the shift register, each of the multiplexers 3312 is connected between a preceding (input side) flip-flop 3311 and a subsequent (output side) flip-flop 3311. The multiplexer 3312 is configured to selectively output the output value of the preceding flip-flop 3311 or the output value of the flip-flop 341a to 341d of the initial value storage 34. Which one of the output values (of the preceding flip-flop 3311 and the flip-flop 341 of the initial value storage 34) to be output from each of the multiplexers 3312 may be selected based on a selecting signal input to the corresponding multiplexer 3312.

The masking information generator 331 further includes an EXOR circuit 3313. The EXOR circuit 3313 outputs an exclusive OR of the output value of the flip-flop 3311a and the output value of the flip-flop 3311d. The output value of the EXOR circuit 3313 is input to the flip-flop 3311a.

Meanwhile, the initial value storage 34 includes (four) flip-flops (FFs) 341a to 341d (hereinafter also collectively called a “flip-flop 341”) corresponding to the number of the scan paths SP (four scan paths in this case). The flip-flops (FFs) 341a to 341d are connected to the respective multiplexers 3312 of the masking information generator 331.

Next, operations of the initial value storage 34 and the masking information generator 331 are described by referring to FIG. 6.

When testing of the LSI 20 is started, a value is recorded in a corresponding the flip-flop 341 of the initial value storage 34 based on a control signal supplied from the LSI tester 20. The value recorded in each flip-flop 341 of the initial value storage 34 is an initial value stored in the test data 50. In the example of FIG. 6, the initial value is 4-bit information. The value of the flip-flop 341 will not be changed thereafter.

The LSI tester 20 inputs control signals based on the test data into the masking information storage 331 at a predetermined time after the initial value is recorded in each of the flip-flops 341. That is, a selecting signal for inputting the value of the flip-flop 341 to a corresponding flip-flop 3311 is supplied to the masking information generator 331. Each of the multiplexers 3312 supplies the output value from the input side flip-flop 341 to the output side flip-flop 3311. As a result, the values of the flip-flops 341 (341a to 341d) are recorded in the respective flip-flops 3311 of the masking information generator 331.

When the masking information (i.e., pseudorandom number) is changed, the LSI tester 20 inputs a selecting signal to the masking information generator 331 to shift the value of the flip-flop 3311 of the masking information generator 331 based on the test data 50. Each of the multiplexers 3312 supplies the output value from the preceding flip-flop 3311 to the subsequent flip-flop 3311 in the masking information generator 331. As a result, the masking information indicated by the flip-flop 3311 contained in the masking information generator 331 is updated.

When the testing of the LSI utilizing one of the test patterns is completed, the value of the flip-flop 3311 in the masking information generator 331 is initialized with the value of the flip-flop 341 stored in the initial value storage 34. For example, the value of the flip-flop 3311 in the masking information generator 331 is initialized with the value of the flip-flop 341 stored in the initial value storage 34 after a new test pattern is supplied to each of the scan paths SP, or before the output response recorded in the flip-flop of each of the scan paths SP is output.

Accordingly, the flip-flop 3311 in the masking information generator 331 includes the same the value (i.e., the masking information) every time the LSI test is initiated by utilizing a new test pattern. As described above, the initial values stored in the initial value storage 34 may be utilized for reducing the number of times that the masking information is inverted. That is, the initial values may cause the masking information generator 331 to generate the masking information that may be inverted a reduced number of times. Accordingly, the value of the flip-flop 3311 in the masking information generator 331 is initialized with such an initial value corresponding to each test pattern. Hence, the masking information utilized for reducing the number of times that the masking information is inverted is generated corresponding to each of the test patterns.

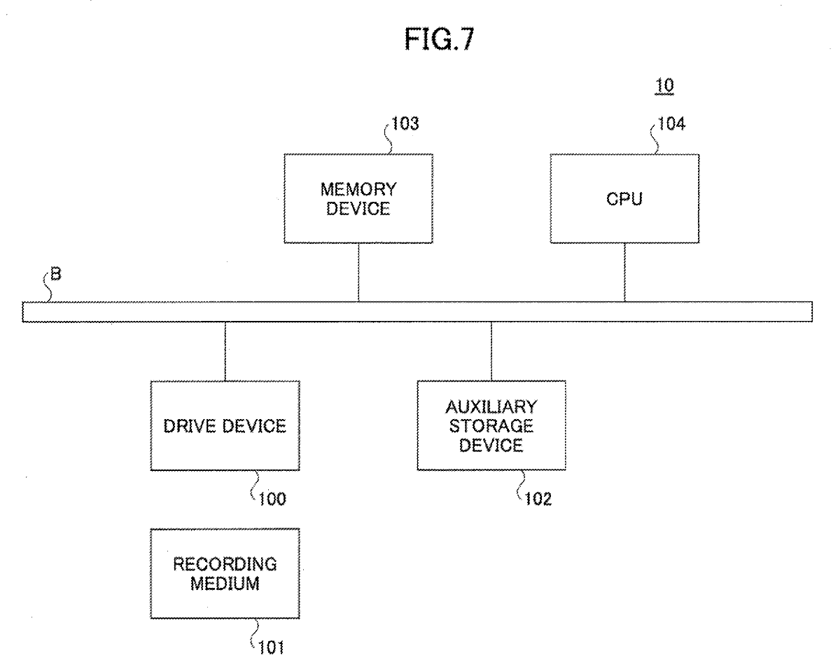

Next, the test data generator device 10 is described below. FIG. 7 is a diagram illustrating a hardware configuration example of the test data generator device 10 according to an embodiment. As illustrated in FIG. 7, the test data generator device 10 includes a drive device 100, an auxiliary storage device 102, a memory device 103 and a CPU 104, which are mutually connected via a bus B.

A computer program that implements various processes in the test data generator device 10 is provided with a recording medium 101. When the recording medium 101 storing the computer program is placed in the drive device 100, the computer program is installed in the auxiliary storage device 102 from the recording medium 101 via the drive device 100. Note that the computer program may not necessarily be installed from the recording medium 101, but may be installed by downloading it from other computers via the network. The auxiliary storage device 102 stores desired files, data and the like, while storing the installed computer program.

On receiving an instruction for activating the computer program, the memory device 103 retrieves the computer program from the auxiliary storage device 102 and loads the retrieved computer program. The CPU 104 executes the computer program loaded on the memory device 103 to implement the functions of the test data generator device 10.

Note that examples of the recording medium 101 include transportable recording media such as a CD-ROM, a DVD disk and a USB memory. Further, examples of the auxiliary storage device 102 include a hard disk drive (HDD) and a flash memory. The recording medium 101 and the auxiliary storage device 102 are both computer-readable recording media.

In addition, the test data generator device 10 may be connected to a display device such as a liquid crystal display, and input devices such as a keyboard and a mouse.

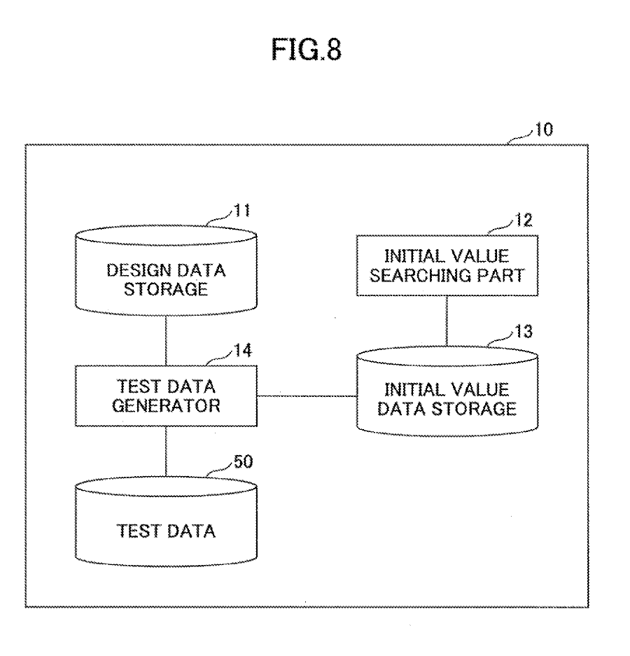

FIG. 8 is a diagram illustrating a functional configuration example of the test data generator device 10 according to an embodiment. As illustrated in FIG. 8, the test data generator device 10 includes a design data storage 11, an initial value searching part 12, an initial value data storage 13 and a test data generator 14. The initial value searching part 12 and the test data generator 14 may be implemented by a computer program installed in the test data generator device 10 when the computer program is executed by the CPU 104. The design data storage 11 and the initial value data storage 13 may be implemented by the auxiliary storage device 102.

The design data storage 11 is configured to store design data for the LSI 30. The design data for the LSI 30 indicates data utilized for fabricating the LSI 30. The design data utilized in this embodiment may include desired information for executing the circuit simulation.

The initial value searching part 12 is configured to search for initial values of the masking information (i.e., pseudorandom numbers), which may be capable of masking the output responses corresponding to unknown values output from part of or all of the flip-flops in the corresponding scan paths SP. The initial value data storage 13 is configured to store initial values searched for by the initial value searching part 12.

The test data generator 14 is configured to generate test data 50 based on the design data and the initial values stored in the initial value data storage 13.

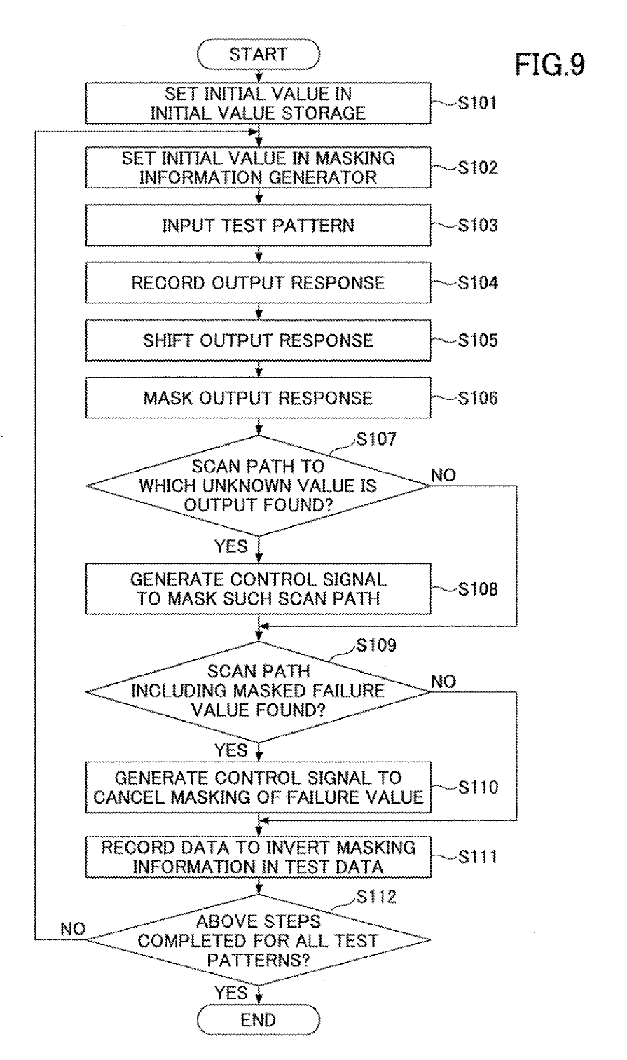

A test data generating procedure performed by the test data generator device 10 is described below. FIG. 9 is a flowchart illustrating an example of a test data generating procedure.

The test data generator 14 constructs (generates) a virtual LSI 30 in a virtual space in the test data generator device 10. The test data generator 14 executes the test data generating procedure illustrated in FIG. 9 to implement the virtual circuit simulation utilizing a virtual LSI 30. Note that the components of the LSI 30 illustrated in the flowchart in FIG. 9 are virtual components of the LSI 30 constructed by the circuit simulation.

In step S101, the test data generator 14 sets the initial values stored in the initial value data storage 13 into initial value storage 34. That is, the initial values stored in the initial value data storage 13 are recorded in the respective flip-flops of the initial value storage 34. The test data generator 14 records in the test data 50 data indicating control signals for recording the initial values in the initial value storage 34. A method of generating the initial values will be described later.

Subsequently, the test data generator 14 copies (records) the initial values recorded in the initial value storage 34 into the respective FFs of the masking information generator 331 (step S102). The test data generator 14 records in the test data 50 data indicating control signals for copying the initial values in the initial value storage 34.

Subsequently, the test data generator 14 causes the test pattern generator 31 to generate test patterns and inputs the generated test patterns into the respective scan paths SP (step S103). When the above step is carried out such that the test patterns are input to the respective flip-flops (FFs) contained in the respective scan paths (i.e., shift registers), a value (i.e., “1” or “0”) constituting the input test pattern is recorded in each of the flip-flops (FFs) of the respective scan paths SP. That is, the above step includes causing one line of a pseudorandom number generated corresponding to one test pattern to shift the respective scan paths, and recording the values in the all the flip-flops in the respective scan paths. Note that one line of a pseudorandom number is composed of bits, the number of which corresponds to the number of scan paths SP. Note also that the test data generator 14 causes the test pattern generator 31 to generate pseudorandom numbers corresponding to the test patterns while recording in the test data 50 data indicating control signals indicating the shifting of the scan paths SP in a generated order of the control signals.

The test data generator 14 supplies a clock signal to the LSI 30 when one of the test patterns is input to the test data 50. As a result, an output response (output value) corresponding to the test pattern is output (recorded) into each of the flip-flops (step S104).

Subsequently, the test data generator 14 shifts the output responses (step S105). Subsequently, the test data generator 14 causes the masking information generator 331 to generate the masking information, and then causes the unknown value masking part 33 to mask the output responses based on the generated masking information (step S106). The test data generator 14 records in the test data 50 control signals indicating output response shifting instructions and masking information generating instructions addressed to the masking information generator 331. Note that each of the flip-slops in the masking information inverter 332 includes a value of “0” in the circuit simulation at the time of generating the test data 50. Thus, the masking information is not inverted at this time.

Subsequently, the test data generator 14 determines whether there is any scan path SP to which the unknown value masking part 33 outputs the unknown values (step S107). If there is a scan path to which the unknown value masking part 33 outputs the unknown value (“YES” in step S107), the test data generator 14 generates the control signal for masking the scan path SP to which the unknown value is output (step S108). The control signal for masking the scan path SP indicates a control signal that may invert apart of the masking information corresponding to the scan path SP.

If there is no scan path to which the unknown value masking part 33 outputs the unknown value (“NO” in step S107), the test data generator 14 subsequently compares the output response before being masked with the masking information to determine whether there is any scan path that includes a masked failure value (step S109). Note that the failure value indicates an output response that may exhibit different values when the LSI 30 is a defective product compared to when the LSI 30 is a non-defective product. That is, the failure value is the output response capable of detecting the defect of the LSI 30.

If there is a scan path that includes the masked failure value (“YES” in step S109), the test data generator 14 generates a control signal to cancel the masking of the failure value output to the scan path SP (step S110). The control signal for cancelling the masking of the failure value in the scan path SP indicates a control signal that inverts a part of the masking information corresponding to the scan path SP.

Subsequently, the test data generator 14 records the control signal for inverting the part of the masking information generated in step S108 or step S110 in the test data 50 by associating it with the timing at which the output response is shifted (step S111). Note that steps subsequent to step S102 are repeated for the intended number of the test patterns. Since step S101 is not carried out while repeating the steps subsequent to step S102, the flip-flops in the initial value storage 34 are not rewritten. On the other hand, the values of the flip-flops 3311 in the masking information generator 331 are initialized with the values of the corresponding flip-flops 341 of the initial value storage 34 (step S102). That is, the flip-flops 3311 in the masking information generator 331 include the same initial values corresponding to the test patterns.

Next, a description is given of a data example indicating the control signals for inverting shifting information or masking information corresponding to the scan path SP recorded in the test data 50 while the process illustrated in FIG. 9 is carried out.

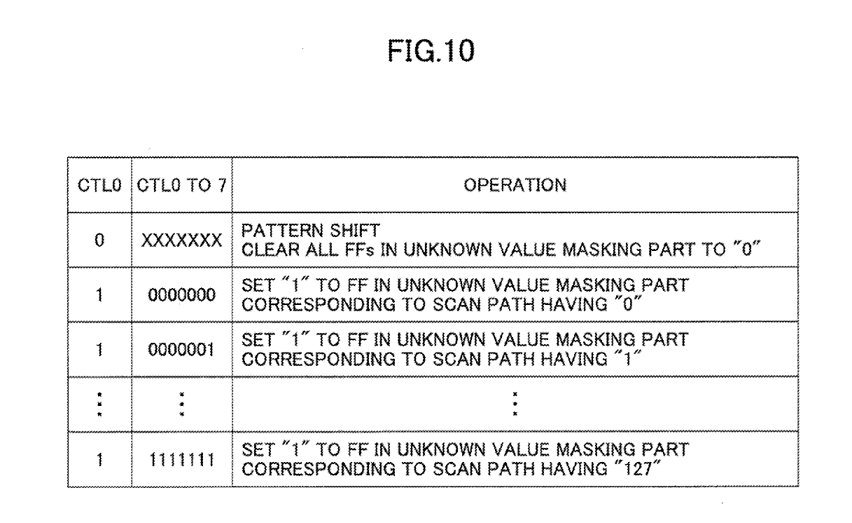

FIG. 10 is a diagram illustrating an example of data indicating the control signals for inverting the shifting information or the masking information. In this example, the number of scan paths SP of the LSI 30 is 128.

In FIG. 10, one line indicates data illustrating one control signal (hereinafter called “control data”). One line of the control data is composed of 8-bit information including CTL0, and CTL1 to CTL7.

The CTL0 is utilized in the shifting of the masking information. That is, the control data including the CTL0 having a value of “0” indicate shifting instructions for the scan paths SP, the test pattern generator 31, the masking information generator 331 and the signature analysis unit 32, regardless of the values of the CTL1 to CTL 7. Note that the shifting of the test pattern generator 31 or the masking information generator 331 indicates generation (output) of a pseudorandom number (i.e., test pattern or mask information).

On the other hand, when the CTL0 includes a value of “1”, the CTL1 to CTL7 are utilized for inverting the masking information. Accordingly, 7 bits of the CTL1 to CTL7 indicate the scan path SP including the masking information to be inverted. Accordingly, “10000000” indicates that the value of “1” is recorded in the flip-flop 3321 corresponding to the first scan path SP in the masking information inverter 332. That is, recording of the value “1” in the flip-flop 3321 may invert the masking information corresponding to the first scan path SP in the masking information inverter 332. That is, if the masking information corresponding to the scan path SP is subject to masking, the masking is cancelled, whereas if the masking information corresponding to the scan path SP is not subject to masking, the masking information is masked.

Note that FIG. 10 illustrates a list of the control data for inverting the shifting information or the masking information, which indicates that not all the control data illustrated in FIG. 10 are recorded in the test data 50.

Further, FIG. 10 illustrates the data example in which the number of the scan paths SP is 128. However, if the number of the scan paths SP is N, the number of bits corresponding the data representing the control signal for inverting the shifting information or the masking information is obtained by “1+[log₂N].

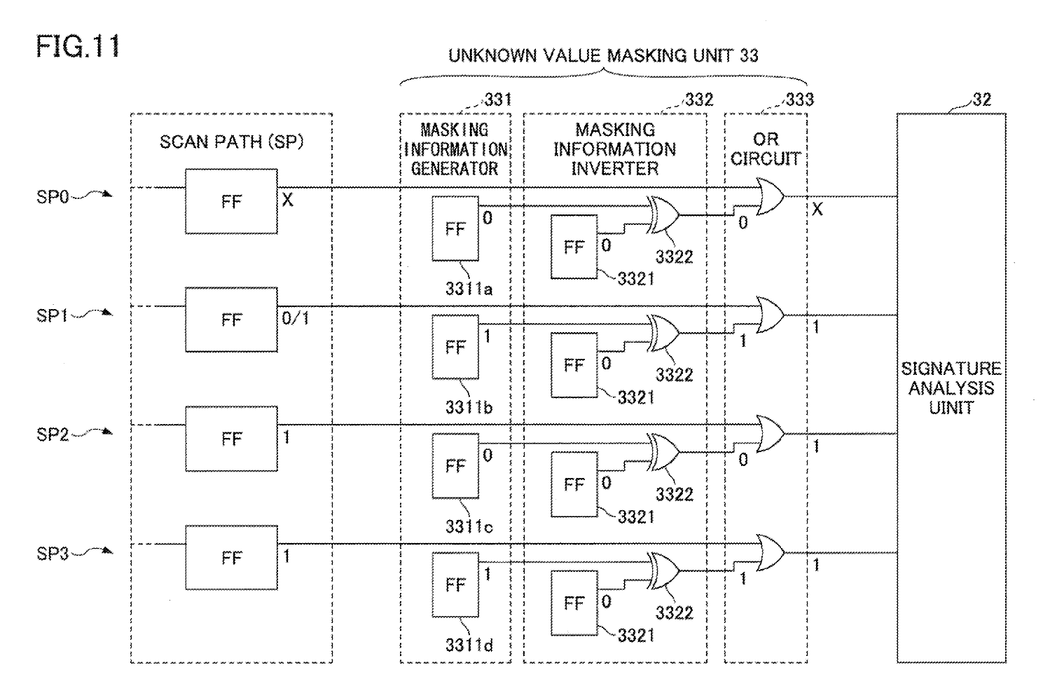

Next, steps subsequent to step S105 illustrated in FIG. 9 are described with reference to a specific example. FIG. 11 is a diagram illustrating a specific example in which whether to invert the masking information is determined. Components illustrated in FIG. 11 similar to those illustrated in FIG. 4, 5 or 6 are provided with the same reference numerals. Note that only the flip-flops are illustrated in the masking information generator 331 in FIG. 11 for convenience of illustration. Further, the initial value storage 34 is omitted from FIG. 11 for convenience of illustration.

FIG. 11 illustrates a state after the output responses corresponding to the test patterns are output to the flip-flops of the corresponding scan paths SP (after executing step S105). In this state, an output response from the scan path SP0, for example, includes an unknown value of “X”. Further, an output response from the scan path SP1, for example, includes a failure value of “0/1”. Moreover, output responses from the scan paths SP2 and SP3, for example, both include a fixed value of “1”. The masking information generated by the masking information generator 331 is, for example, determined as “0”, “1”, “0” and “1” corresponding to the scan paths SP0, SP1, SP2 and SP3. That is, the output responses from the scan paths SP1 to SP3 are subject to masking.

Note that although the output response from the scan path SP0 is the unknown value of “X”, the output response from the scan path SP0 is unmasked. Further, the output response from the scan path SP1 is the failure value. Accordingly, if the failure value output from the scan path SP1 is masked, the defect (of the LSI 30) may not be detected. Note that the output response from the scan path SP3 is the fixed value. The fixed value indicates a fixed output response regardless of the presence or the absence of the defect (of the LSI 30). Since the fixed value is output regardless of the presence or the absence of the defective product, the fixed value may be masked without inducing an adverse effect. Note that each of the flip-flops 3321 of the masking information inverter 332 includes a value of “0” in the circuit simulation at the time of generating the test data 50. That is, the masking information corresponding to any of the scan paths SP may not be subject to inverting.

As may be clear from the above, the output response of the scan path SP0 may need to be masked and the masked output response of the scan path SP1 may need to be cancelled in the state illustrated in FIG. 11. That is, the respective masking information items (i.e., output responses) from the scan paths SP0 and SP3 may need to be masked.

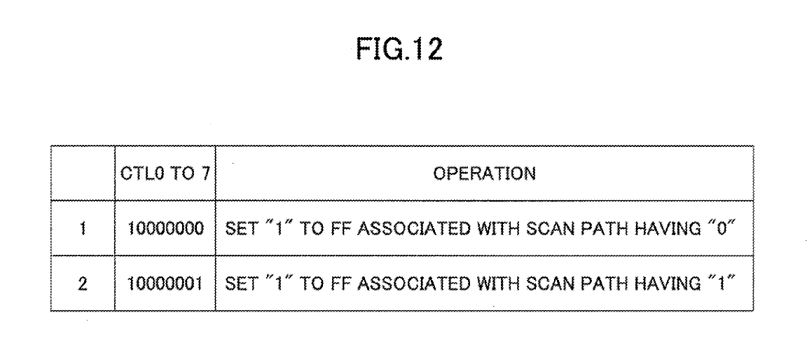

Accordingly, the test data generator 14 records in the test data 50 control data that invert the masking of the scan paths SP0 and SP1. Note that an example of the control data recorded in the test data 50 is illustrated in FIG. 12.

FIG. 12 is a diagram illustrating a specific example of the control data for inverting the masking information recorded in the test data 50.

In FIG. 12, the control data value (CTL0 to 7) in a first line corresponds to “10000000”. Accordingly, the control data in the first line of the example records a value of “1” in the flip-flop 3321 corresponding to the scan path SP0 in the masking information inverter 332. Further, the control data value (CTL0 to 7) in a second line of the example corresponds to “10000001”. Accordingly, the control data in the second line records a value of “1” in the flip-flop 3321 corresponding to the scan path SP1 in the masking information inverter 332.

Next, an actual test of the LSI 30 performed by the LSI tester 20 based on the test data 50 generated as above is described below.

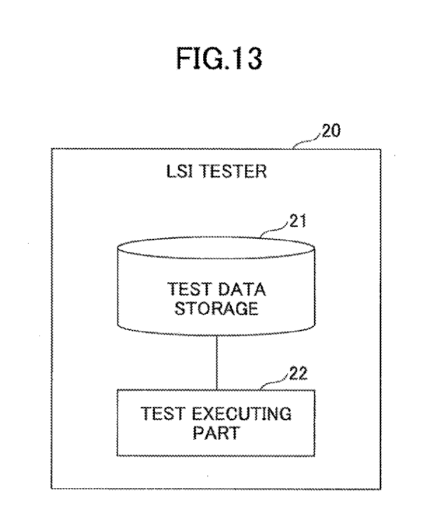

FIG. 13 is a diagram illustrating a configuration example of the LSI tester 20 according to an embodiment. As illustrated in FIG. 13, the LSI tester 20 includes a test data storage 21 and a test executing part 22.

The test data storage 21 is a storage device configured to store the test data 50 generated by the test data generator device 10. The test executing part 22 is configured to perform a test for detecting a defect of the LSI 30 by decoding the test data 50 stored in the test data storage 21 and inputting control signals or the like to the LSI 30. The test executing part 22 detects the defect of the LSI 30 by comparing the compressed output response output from the signature analysis unit 32 with the expected value.

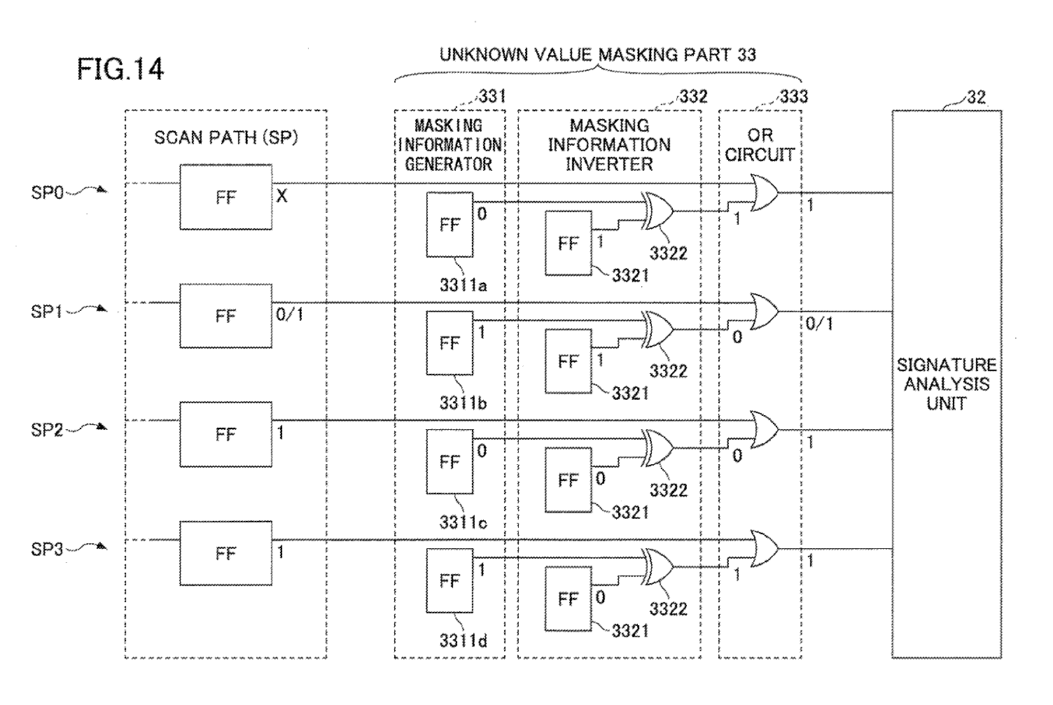

Basically, the test executing part 22 performs processes based on the test data 50 generated by the test data generator 14. Accordingly, a procedure performed by the test executing part 22 is the same as a procedure performed by the test data generator 14 illustrated in FIG. 9. However, an inverting process of inverting the mask information at the time of executing the actual test illustrated in FIG. 14 may differ from the generating process of generating the test data 50 illustrated in FIG. 9.

Accordingly, the inversion of the masking information is described below. FIG. 14 is a diagram illustrating an example in which the masking information is inverted when the actual LSI test is performed. Components illustrated in FIG. 14 similar to those illustrated in FIG. 11 are provided with the same reference numerals. Specifically, FIG. 14 illustrates the example in which the masking information is inverted when the actual LSI test is performed based on the test data 50 including the control data illustrated in FIG. 12.

In FIG. 14, the masking information generated by the masking information generator 331 is determined as “0”, “1”, “0” and “1” corresponding to the scan paths SP0, SP1, SP2 and SP3, in the same manner as the example illustrated in FIG. 11. The generated order of the pseudorandom numbers (masking information) generated by the masking information generator 331 is reproducible, because the masking information in the circuit simulation and the masking information in the actual LSI test generated at the same timing are matched.

However, the control signals based on the control data (see FIG. 12) included in the test data 50 are supplied to the LSI 30 by the LSI tester 20 in the example illustrated in FIG. 14. That is, “1” is recorded in the flip-flop 3321 corresponding to the scan path SP0, and also in the flip-flop 3321 corresponding to the scan path SP1 in the masking information generator 332. Accordingly, the respective masking information associated with the scan paths SP0 and SP2 is inverted. Consequently, an output response from the scan path SP1 results in “1”. Further, an output response from the scan path SP1 results in a failure value. As a result, the unknown value may be prevented from being supplied to the signature analysis unit 32. In addition, the failure value may be supplied to the signature analysis unit 32.

As is clear from the examples of FIGS. 12 and 14, the amount of the control data for inverting the masking information may be increased or reduced based on the number of times that the masking information is inverted. That is, if the masking information is inverted numerous times, the amount of the control data may be increased, whereas if the masking information is inverted fewer times, the amount of the control data may be reduced. The control data are stored in the test data 50. Thus, the increase or decrease of the control data may affect the increase or decrease of the test data 50.

In the meantime, the number of times that the unknown value is output (frequency of generating the unknown value) is not uniform but is biased in the respective flip-flops in the scan paths. This may result from bias in the sequential circuit elements that output the unknown values.

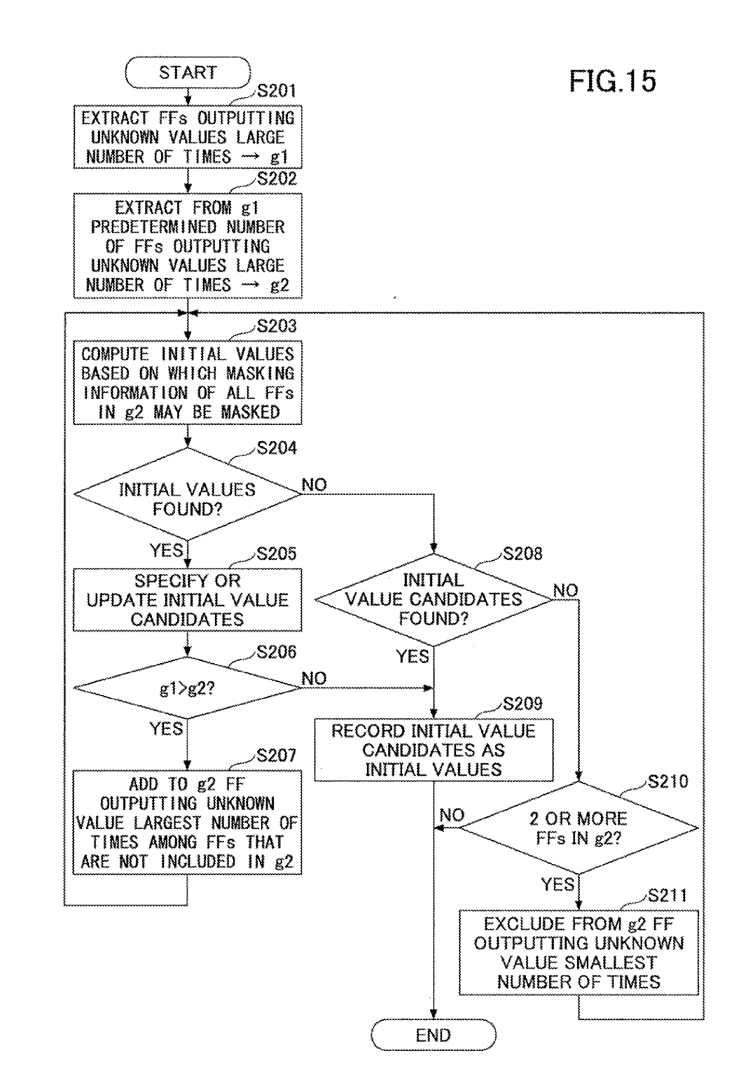

The unknown values are output from ubiquitous parts. Hence, the initial value searching part 12 of the test data generator device 10 utilizes such ubiquity of output parts outputting the unknown values to generate the initial values of the masking information generator 331, based on which the number of times that the masking information is inverted is reduced, according to a procedure illustrated in FIG. 15.

FIG. 15 is a flowchart illustrating an example of a masking information initial value generating procedure. The procedure illustrated in FIG. 15 may be performed before the test data 50 generating procedure (see FIG. 9) is carried out.

In step S201, the initial value searching part 12 extracts the flip-flops outputting one or more unknown values among the flip-flops in each of the scan paths SP in the circuit simulation of the LSI 30. The number of times that each flip-flop outputs the unknown value may be counted in the circuit simulation executed before step S201. The counted number of times may be recorded in the memory device 103 or auxiliary storage device 102 by associating it with an identifier of the corresponding flip-flop. Note that a group of the flip-flops extracted in step S201 is hereinafter called a “flip-flop group g1”.

Subsequently, the initial value searching part 12 extracts a predetermined number of flip-flops from the flip-flop group g1 in the order of the largest number of times to the smallest number of times that the flip-flop outputs the unknown value (step S202). That is, the order of top N flip-flops (N is an integer of 0 or more) that output unknown values a large number of times are extracted. Note that a group of the flip-flops extracted in step S202 is hereinafter called a “flip-flop group g2”.

Subsequently, the initial value searching part 12 computes initial values of the masking information generator 331 that may be capable of masking output responses of all the flip-flops in flip-flop group g2 (step S203). Such initial values may be obtained (or searched for) by computing simultaneous equations.

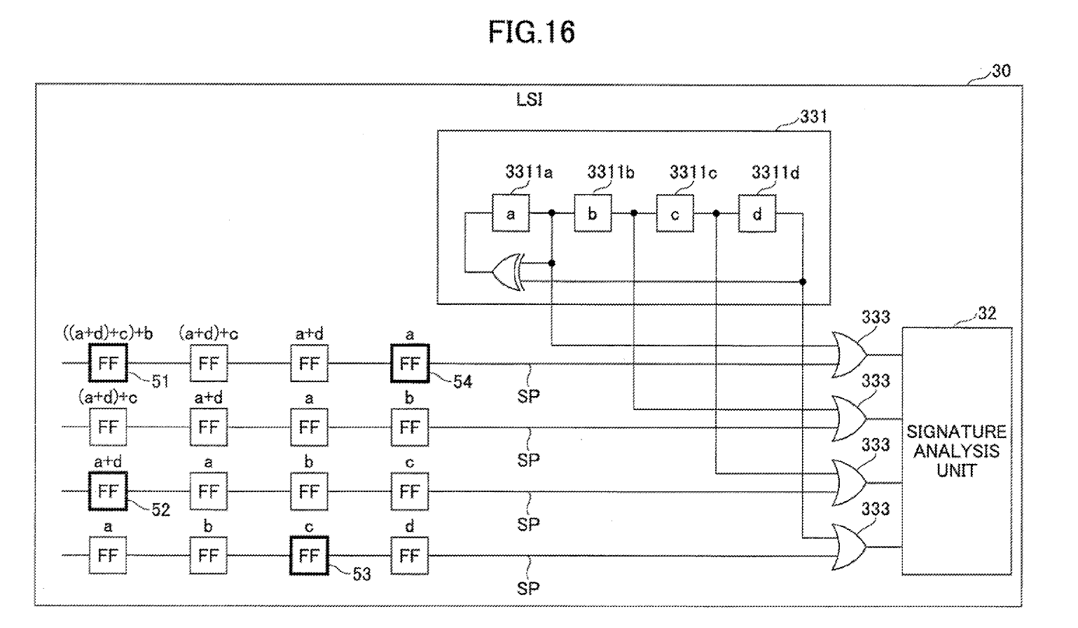

FIG. 16 is a diagram illustrating an example of a method of searching for initial values of the masking information generator 331 that may be capable of masking the output responses of all the flip-flops in a specific flip-flop group. In the example of FIG. 16, the number of scan paths SP is four, and each of the scan paths includes four flip-flops. In this example, a direction of the scan paths SP is called a row direction and a direction perpendicular to the scan paths SP is called a column direction. Thus, the flip-flops arranged in a 4 (row)*4 (column) matrix are illustrated in FIG. 16. The row numbers of the four rows in the matrix are determined as 1, 2, 3 and 4 from the top row. The column numbers of the four columns in the matrix are determined as 1, 2, 3 and 4 from the rightmost column (from the signature analysis unit 32 side).

Initially, a variable indicating an initial value is assigned to each of the flip-flops 3311 (i.e., 3311a to 3311d) in the masking information generator 331. Since the number of scan paths SP is four, the number of flip-flops 3311 in the masking information generator 331 is four. In FIG. 16, suffixes “a”, “b”, “c” and “d” are assigned as the variables that indicate the initial values of the flip-flops 3311a, 3311b, 3311c and 3311d in this order.

Subsequently, current values of the respective flip-flops 3311 (i.e., 3311a to 3311d) in the masking information generator 331 are assigned to the flip-flops corresponding to the scan paths SP in a first column. Accordingly, the values “a”, “b”, “c” and “d” are assigned to the flip-flops in the first column in the order of first, second, third and fourth rows.

Subsequently, the values of the flip-flops 3311 in the masking information generator 331 are shifted. That is, respective pseudorandom numbers subsequent to the initial values of the flip-flops 3311 are generated. In FIG. 16, the values of the flip-flops 3311 are shifted in a clockwise direction. However, an exclusive OR of the output value of the flip-flop 3311a and the output value of the flip-flop 3311d is output into the flip-flop 3311a by the EXOR circuit 3313. As a result, the values of the flip-flops 3311a to 3311d in the masking information generator 331 are “a+d”, “a”, “b” and “d” in the order of the flip-flops 3311a, 3311b, 3311c and 3311d. Note that the exclusive OR is expressed by a “+” for convenience of illustration in FIG. 16. For example, “a+d” represents an exclusive OR of “a” and “d”.

Subsequently, the above current values of the respective flip-flops 3311 (i.e., 3311a to 3311d) in the masking information generator 331 are assigned to the flip-flops associated with the respective scan paths SP in a second column. Accordingly, the values “a+d”, “a”, “b” and “c” are assigned to the flip-flops in the second column in the order of the first, second, third and fourth rows.

Subsequently, the values of the flip-flops 3311 in the masking information generator 331 are shifted. As a result, the values of the flip-flops 3311a to 3311d in the masking information generator 331 are “(a+d)+C”, “a+d”, “a” and “b” in the order of the flip-flops 3311a, 3311b, 3311c and 3311d.

Subsequently, the above current values of the respective flip-flops 3311 (i.e., 3311a to 3311d) in the masking information generator 331 are assigned to the flip-flops corresponding to the scan paths SP in a third column. Accordingly, the values “(a+d)+c”, “a+d”, “a” and “b” are assigned to the flip-flops in the third column in the order of the first, second, third and fourth rows.

Subsequently, the values of the flip-flops 3311 in the masking information generator 331 are shifted. As a result, the values of the flip-flops 3311a to 3311d in the masking information generator 331 are “((a+d)+c)+b”, “(a+d)+c”, “a+b” and “a” in the order of the flip-flops 3311a, 3311b, 3311c and 3311d.

Subsequently, the above current values of the respective flip-flops 3311 (i.e., 3311a to 3311d) in the masking information generator 331 are assigned to the flip-flops corresponding to the scan paths SP in a fourth column. Accordingly, the values “((a+d)+c)+b”, “(a+d)+c”, “a+b” and “a” are assigned to the flip-flops in the fourth column in the order of the first, second, third and fourth rows.

When the values are assigned to all the flip-flops in the associated scan paths SP, the simultaneous equations are computed for the values assigned to the flip-flops in the flip-flop group g2. In FIG. 16, the flip-flop group g2 includes the flip-flops 51, 52, 53 and 54. In this case, a condition for the initial values the masking information of all the flip-flops in the flip-flop group g2 is masked may be represented by the following simultaneous equations.

((a+d)+c)+b=1

a+d=1

c=1

a=1

The following solutions are obtained by computing the above simultaneous equations.

a=1

b=1

c=1

d=0

In step S203 (see FIG. 15), the initial values which may be capable of masking the output responses of all the flip-flops in the flip-flop group g2 are computed. Note that the above-described solutions (a=1, b=1, c=1 and d=1) are the computed initial values which may be capable of masking the output responses of all the flip-flops in the flip-flop group g2. Note that the initial values may be searched for in the same manner as the above-described method in a case where the number of scan paths SP is five or more, and the number of flip-flop columns perpendicular to the respective scan paths SP is five or more.

Subsequent to step S203, the initial value searching part 12 determines whether there are initial values which may be capable of masking the output responses of all the flip-flops in flip-flop group g2. The above determination corresponds to the determination as to whether there are solutions of the above simultaneous equations. In the example of FIG. 16, the solutions of the above simultaneous equations are obtained. Thus, the process is moved to step S205.

In step S205, the initial value searching part 12 records the obtained solutions as initial value candidates in the memory device 103 or the auxiliary storage device 102. As will be described later, processes subsequent to step S203 are repeatedly carried out. Thus, if the initial value candidates are already recorded in the memory device 103 or the auxiliary storage device 102, the initial value candidates may be updated or replaced with newly acquired solutions. Note that the initial values are not determined at this time because there may be initial values which may be capable of masking the output responses of a far larger number of flip-flops than the number of flip-flops contained in the flip-flop group g2.

Subsequently, the initial value searching part 12 determines whether there are flip-flops that are contained in the flip-flop group g1 but are not contained in the flip-flop group g2 (step S206). That is, whether the flip-flop group g1 includes a greater number of flip-flops compared to the number of flip-flops contained in the flip-flop group g2 is determined.

If the flip-flop group g1 includes the number of flip-flops greater than the number of flip-flops contained in the flip-flop group g2 (“YES” in step S206), the initial value searching part 12 adds to the flip-flop group g2 the flip-flop that outputs the unknown value the largest number of times (step S207). Subsequently, the initial value searching part 12 repeatedly carries out the processes subsequent to step S203. That is, the initial values on which are based the masking information of all the flip-flops including the newly added flip-flop in the flip-flop group g2 are searched for.

If there is no flip-flop that is included in the flip-flop group g1 but is not included in the flip-flop group g2 (“NO” in step S206), the initial value searching part 12 records the current initial value candidates as the initial values in the initial value data storage 13 (step S209).

In the meantime, if the solutions of the simultaneous equations are not obtained in step S203 (“NO” in step S204), the initial value searching part 12 determines whether the initial value candidates are recorded in the memory device 103 or the auxiliary storage device 102 (step S208). If the initial value candidates are recorded in the memory device 103 or the auxiliary storage device 102 (“YES” in step S208), the initial value searching part 12 records the current initial value candidates as the initial values in the initial value data storage 13 (step S209).

If, on the other hand, the initial value candidates are not recorded in the memory device 2 or the auxiliary storage device 2 (“NO” in step S208), the initial value searching part 12 determines whether the flip-flop group 2 includes two or more flip-flops (step S210). If the flip-flop group g2 includes two or more flip-flops (“YES” in step S210), the initial value searching part 12 excludes from the flip-flop group g2 the flip-flop that outputs the unknown value the smallest number of times (step S11). Subsequently, the initial value searching part 12 repeatedly carries out the processes subsequent to step S203. That is, the solutions of the simultaneous equations are obtained by deleting the flip-flop subject to the simultaneous equations.

If the flip-flop group g2 includes only one flip-flop (“NO” in step S210), the initial value searching part 12 terminates the initial value searching process without recording the initial values.

As described above, the searched for or computed initial values may be capable of masking the output responses (i.e., pseudorandom numbers) of the largest possible number of the flip-flops among all the flip-flops that output the unknown value at least once. In the embodiments described above, the initial values, which may be capable of masking the output responses of a part of or all of the flip-flops that output the unknown value at least once, may be set in the masking information generator 331 for each of the test patterns. As a result, the control data for inverting the masking information corresponding to the unknown values of the respective flip-flops may be no longer necessary. Thus, it may be possible to eliminate the control data for inverting the masking information corresponding to the unknown values of the respective flip-flops, which may further reduce the amount of the test data 50.

Note that in the above embodiments, even if the output responses of the flip-flops that output unknown values are masked 50% or less of the number of times, such masking may still provide an adequate effect on the reduction of the control data. That is, the masking of the unknown values may not interfere the test result, provided that the unknown numbers are not the failure value. For example, even if the output responses of the flip-flop, which outputs the unknown value once and the fixed value 9 times corresponding to 10 different test patterns, are constantly masked, it may not be necessary to invert the mask information corresponding to the output responses of the fixed values. In this case, the number of times that the masking information is inverted may be reduced corresponding to the unknown value that has been output once.

Note that in the embodiments, the masking information generator 331 of the LSI 30 is an example of a generator. In addition, the masking information inverter 332 is an example of an inverter. Further, the initial value storage 34 is an example of storage.

Moreover, the initial value searching part 12 of the test data generator device 10 is an example of a searching part.

According to the above embodiments, it may be possible to reduce the number of times that the masking information applied to the output responses corresponding to the test patterns is inverted.

The embodiments described above are not limited thereto. Various modifications or alterations may be made within the scope of the inventions described in the claims.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority or inferiority of the invention. Although the embodiments of the present invention have been described in detail, it should be understood that the various changes, substitutions, and alterations could be made hereto without departing from the spirit and scope of the invention.

What is claimed is:

1. A semiconductor integrated circuit comprising:
a plurality of shift registers to which test patterns are supplied;
a pseudorandom number generator configured to generate, based on the test patterns supplied to the shift registers, pseudorandom numbers utilized as masking information corresponding to output responses of the shift registers;
a masking information inverter configured to invert, on receiving a first control signal, the masking information corresponding to the output responses of the shift registers indicated by the first control signal; and
an initial value storage configured to store initial values of the pseudorandom numbers, wherein
the pseudorandom numbers generated by the pseudorandom number generator are, on receiving a second control signal, initialized with the initial values of the pseudorandom numbers stored in the initial value storage.

2. The semiconductor integrated circuit as claimed in claim 1, further comprising:
a plurality of flip-flops contained in each of the shift registers, wherein
the initial value storage stores the initial values of the pseudorandom numbers, based on which the pseudorandom number generator generates the pseudorandom numbers utilized for masking the output responses corresponding to unknown values output based on the test patterns by a part of the flip-flops or all of the flip-flops.

3. A method of testing a semiconductor integrated circuit performed by a testing device, the semiconductor integrated circuit including a semiconductor integrated circuit including a plurality of shift registers to which test patterns are supplied; a pseudorandom number generator configured to generate, based on the test patterns supplied to the shift registers, pseudorandom numbers utilized as masking information corresponding to output responses of the shift registers; a masking information inverter configured to invert, on receiving a first control signal, the masking information corresponding to the output responses of the shift registers indicated by the first control signal; and an initial value storage configured to store initial values of the pseudorandom numbers, the pseudorandom numbers generated by the pseudorandom number generator being, on receiving a second control signal, initialized with the initial values of the pseudorandom numbers stored in the initial value storage, the method comprising:
supplying the first control signal to the semiconductor integrated circuit based on test data generated in advance; and
supplying the second control signal to initialize the pseudorandom numbers for the corresponding test patterns.

4. An information processing apparatus for processing the semiconductor integrated circuit as claimed in claim 1, comprising:
an initial value searching part configured to search for the initial values of the pseudorandom numbers, which are capable of masking the output responses corresponding to the unknown values output by a part of flip-flops or all of the flip-flops contained in a corresponding one of the shift registers included in the semiconductor integrated circuit.

5. The information processing apparatus as claimed in claim 4, wherein
the initial value searching part searches for the initial values of the pseudorandom numbers, which are capable of masking the output responses of the all of the flip-flops or the part of the flip-flops that outputs the unknown values a largest number of times.

6. A non-transitory computer-readable medium storing a program, which, when processed by a processor, causes a computer to execute a searching process, the searching process comprising:
searching for initial values of pseudorandom numbers, which are capable of masking output responses corresponding to unknown values output by a part of flip-flops or all of the flip-flops contained in a corresponding one of shift registers included in a semiconductor integrated circuit, wherein
the semiconductor integrated circuit includes:
the shift registers to which test patterns are supplied;
a pseudorandom number generator configured to generate, based on the test patterns supplied to the shift registers, the pseudorandom numbers utilized as masking information corresponding to the output responses of the shift registers;
a masking information inverter configured to invert, on receiving a first control signal, the masking information corresponding to the output responses of the shift registers indicated by the first control signal; and
an initial value storage configured to store the initial values of the pseudorandom numbers, wherein the pseudorandom numbers generated by the pseudorandom number generator are, on receiving a second control signal, initialized with the initial values of the pseudorandom numbers stored in the initial value storage.

7. The non-transitory computer-readable medium as claimed in claim 6, wherein
the searching process includes searching for the initial values which are capable of masking the output responses of all of the flip-flops, or a part of the flip-flops that outputs the unknown values a largest number of times.
